(19) United States
(12) Patent Application Publication
(10) Pub. No.: US 2025/0267893 A1
(43) Pub. Date: Aug. 21, 2025

(54) SILICON CARBIDE POWER DEVICES HAVING EXPANDED CREEPAGE DISTANCES

(71) Applicant: Wolfspeed, Inc., Durham, NC (US)

(72) Inventors: Edward R. Van Brunt, Cary, NC (US); Joseph Liu, Cary, NC (US)

(21) Appl. No.: 18/581,339

(22) Filed: Feb. 19, 2024

(51) Int. Cl. H01L 29/78; H01L 23/29; H01L 23/31; H01L 29/16; H01L 29/66

(52) U.S. Cl. CPC H10D 30/665; H01L 23/293; H01L 23/3171; H10D 30/0291; H10D 62/8325

(57) ABSTRACT

A semiconductor device having expanded creepage distance includes a drift region comprising an active region, including at least one active element therein, and an edge termination region around at least a portion of a perimeter of the active region when viewed in plan view. The semiconductor device further includes a passivation structure on the edge termination region, the passivation structure including an insulating layer on the drift region, and a first polymer layer on the insulating layer opposite the drift region. The first polymer layer includes a top surface that is nonplanar.

### FIELD

The present disclosure relates generally to semiconductor devices, and more particularly relates to passivation edge structures for semiconductor devices.

### BACKGROUND

Semiconductor devices such as transistors and diodes are ubiquitous in modern electronic systems and devices. Wide-bandgap semiconductor materials such as gallium nitride (GaN) and silicon carbide (SiC) are being increasingly utilized in semiconductor devices to push the boundaries of device performance, particularly in areas such as switching speed, power handling capability, and heat dissipation. Examples of the use of such wide-bandgap materials can be found in individual devices such as metal-oxide-semiconductor field-effect transistors (MOSFETs), insulated gate bipolar transistors (IGBTs), Schottky barrier diodes, PIN diodes, high electron mobility transistors (HEMTs), and integrated circuits such as monolithic microwave integrated circuits (MMICs) that may include one or more individual devices.

Semiconductor devices typically include an active region in which one or more active components are provided. In semiconductor devices manufactured to support high voltages and currents, concentration of electric fields can interfere with the proper operation thereof. Concentration of electric fields is especially problematic at edges of the semiconductor die. Accordingly, an edge termination region typically surrounds the active region about a perimeter of the semiconductor die to reduce electric fields at the edges of active region. Without an edge termination region, electric fields would concentrate at the edges of the die and cause the performance of the die to suffer. For example, the breakdown voltage, leakage current, and/or reliability of the die may be significantly reduced.

Semiconductor devices are typically formed using so-called wafer processing, where multiple devices are formed on a single semiconductor wafer, where each semiconductor device includes its own edge termination. Once wafer level processing is completed, the semiconductor wafer is cut (“diced”) to singulate the individual semiconductor devices. Semiconductor die are typically passivated during a passivation process. Passivation generally involves the deposition of a protective layer of material, such as silicon nitride or an oxide layer like silicon dioxide, onto the surface of a semiconductor device. The protective layer is typically formed during wafer level processing, but can alternatively be formed on a die-by-die basis. This passivation layer serves to protect the underlying structures of the die from damage and contamination during the packaging process and subsequent use. Conventional power device structures are often passivated at the edge termination region of the device using a flat layer of organic passivation material, such as polyimide and silicone gel.

The art continues to seek improved edge termination structures for semiconductor devices capable of overcoming challenges associated with conventional semiconductor devices.

### SUMMARY

The present invention, as manifested in one or more embodiments, is directed generally to novel semiconductor devices, and more particularly to organic passivation edge structures for power semiconductor devices. A semiconductor device may include an active region, an edge termination region that is arranged along a perimeter of the active region, and a passivation structure that may form a die seal along the edge termination region. The passivation edge structure may include a number of passivation layers configured in a manner that not only improves mechanical strength and adhesion of the passivation structure along the edge termination region, but increases a creepage distance (discussed below) to thereby improve reliability of the semiconductor device.

In accordance with an embodiment of the present disclosure, a semiconductor device having expanded creepage distance includes a drift region comprising an active region, including at least one active element therein, and an edge termination region around at least a portion of a perimeter of the active region when viewed in plan view. The semiconductor device further includes a passivation structure on the edge termination region, the passivation structure including an insulating layer on the drift region, and a first polymer layer on the insulating layer opposite the drift region. The first polymer layer includes a top surface that is nonplanar.

In some embodiments, the first polymer layer may be configured to extend horizontally, parallel to a top surface of the drift region, from a peripheral edge of the edge termination region toward the active region over a majority of the edge termination region. In some embodiments, the first polymer layer may be configured to extend horizontally from the peripheral edge of the edge termination, across the top surface of the insulating layer, and partially into the active region. In some embodiments, the semiconductor device further includes a second polymer layer between the insulating layer and the first polymer layer. The second polymer layer may include a planar top surface. The second polymer layer may include one or more trenches extending vertically from a top surface of the second polymer layer at least partially into the second polymer layer, the first polymer layer conformally covering at least a portion of the top surface of the second polymer layer.

In accordance with another embodiment of the present disclosure, a semiconductor device having expanded creepage distance includes: a drift region; an active region including a portion of the drift region; an edge termination region in the drift region and around at least a portion of a perimeter of the active region when viewed in plan view; and a passivation structure on the edge termination region. The passivation structure includes an insulating layer on the drift region, a first polymer layer on the insulating layer opposite the drift region, and a mold compound on a peripheral edge of the edge termination region, wherein the mold compound does not extend over a top surface of the active region.

In some embodiments, at least one of the top surface, a side surface and a bottom surface of the mold compound includes at least one trench therein. In some embodiments, the mold compound may extend around the peripheral edge of the edge termination region when viewed in plan view. In some embodiments, the top surface of the first polymer layer has a nonplanar cross-sectional profile. In some embodiments, the active region of the semiconductor device includes at least one MOSFET, the semiconductor device further including a second polymer layer on the first polymer layer and the mold compound, the second polymer layer extending horizontally from an outer edge of the mold compound, opposite the peripheral edge of the edge termination region, to a top surface of a source electrode of the MOSFET in the active region.

In accordance with yet another embodiment of the present disclosure, a method of fabricating a semiconductor device includes: providing a drift region including an active region, which includes at least one active element therein, and an edge termination region around at least a portion of a perimeter of the active region when viewed in plan view; and providing a passivation structure on the edge termination region. The passivation structure includes an insulating layer on the drift region, and a first polymer layer on the insulating layer opposite the drift region. The method further includes forming at least one notch in the first polymer layer.

In some embodiments, the method further includes providing one or more openings in the top surface of the first polymer layer, the one or more openings extending vertically, perpendicular to a top surface of the drift region, at least partially into the first polymer layer. In some embodiments, the first polymer layer includes a first end and a second end opposite the first end, the first end of the first polymer layer being vertically coplanar with a peripheral edge of the edge termination region, and the second end of the first polymer layer being on a top surface of a source electrode of a metal-oxide-semiconductor field-effect transistor in the active region. In some embodiments, the method further includes providing a second polymer layer between the insulating layer and the first polymer layer. The second polymer layer may comprise a planar top surface.

In accordance with an embodiment of the present disclosure, a method of forming a semiconductor device includes: providing a drift region; providing an active region including a portion of the drift region; providing an edge termination region in the drift region and around at least a portion of a perimeter of the active region when viewed in plan view; and providing a passivation structure on the edge termination region. The passivation structure includes an insulating layer on the drift region, a first polymer layer on the insulating layer opposite the drift region, and a mold compound on a peripheral edge of the edge termination region, the mold compound having a top surface that is coplanar with a top surface of the first polymer layer.

In accordance with still another embodiment of the present disclosure, a method of forming a semiconductor wafer that includes a plurality of un-singulated semiconductor die thereon is provided. The method includes: forming a drift region on a substrate, the drift region including a plurality of active regions that correspond to the respective semiconductor die and a plurality of edge termination regions that extend around at least a portion of a perimeter of the respective active regions when viewed in plan view; forming an insulating layer on the drift region; forming a first polymer layer on the insulating layer opposite the drift region; and forming one or more openings in the top surface of the first polymer layer, the one or more openings extending vertically, perpendicular to a top surface of the drift region, at least partially into the first polymer layer.

Techniques of the present inventive concept can provide substantial beneficial technical effects. By way of example only and without limitation, techniques according to embodiments of the present disclosure may provide one or more of the following advantages, among other benefits:
reduces the effects of electrochemical migration in a semiconductor device by increasing creepage distance, thereby improving device reliability;
allows for the use of organic passivation materials (e.g., polyimide) in the device while allowing the device to meet prescribed creepage time requirements associated with high-voltage, temperature, humidity and bias testing;
easily integrates with existing fabrication processes without significantly increasing device fabrication complexity.

These and other features and advantages of the present inventive concept will become apparent from the following detailed description of illustrative embodiments thereof, which is to be read in connection with the accompanying drawings.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIG. 1A is a plan view depicting a top surface of an exemplary semiconductor device, according to the present disclosure;

FIG. 1B is a cross-sectional view depicting a portion of the exemplary semiconductor device of FIG. 1A, taken along line A-A′, for embodiments where the semiconductor device includes a MOSFET;

FIG. 2 is a cross-sectional view depicting at least a portion of an exemplary power semiconductor device including a passivation structure employing an organic passivation layer;

FIG. 3 is a cross-sectional view depicting at least a portion of an exemplary power semiconductor device including a passivation structure employing an organic passivation layer configured to increase a creepage path length in the semiconductor device, according to one or more embodiments of the present disclosure;

FIG. 4 is a cross-sectional view illustrating at least a portion of an exemplary semiconductor device including a passivation structure configured to increase creepage distance in the semiconductor device, according to an alternative embodiment of the present disclosure;

FIG. 5 is a cross-sectional view illustrating at least a portion of an exemplary semiconductor device including a passivation structure employing a corrugated overmold structure configured to further increase creepage distance in the semiconductor device, according to one or more embodiments of the present disclosure;

FIG. 6 is a cross-sectional view depicting at least a portion of an exemplary semiconductor device including a passivation structure comprising a shaped top encapsulation structure that allows the mold compound to encapsulate die edges and a top surface, according to one or more embodiments of the present disclosure;

FIG. 7 is a cross-sectional view depicting at least a portion of an exemplary semiconductor device including a passivation structure comprising multiple polyimide layers, according to one or more embodiments of the present disclosure; and

FIG. 8 is a cross-sectional view depicting at least a portion of an exemplary semiconductor device including a passivation structure comprising a second polyimide layer having a corrugated top surface, according to one or more embodiments of the present disclosure.

It is to be appreciated that elements in the figures may be illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present invention, as manifested in one or more embodiments thereof, may be described herein in the context of a power MOSFET device or power module including such a device, and more specifically to embodiments of an organic passivation structure for a power semiconductor device, which may be suitable for use in a wireless communications environment, among other beneficial applications. It is to be appreciated, however, that the invention is not limited to the specific devices, circuits, systems and/or methods illustratively shown and described herein. Rather, it will become apparent to those skilled in the art given the teachings herein that numerous modifications to the embodiments shown are contemplated and are within the scope of the present disclosure. That is, no limitations with respect to the embodiments shown and described herein are intended or should be inferred.

Reference may be made herein to “exemplary” embodiments, devices, circuits, methods, etc. As used herein, the term “exemplary” is intended to mean “serving as an example, illustration, instance or explanation,” and is not intended to imply that an embodiment, device, circuit, method, etc., serves as a model to be accurately copied. In other words, any embodiment, device, circuit, method, etc., described herein as being “exemplary” should not necessarily be interpreted as being preferable or advantageous over other embodiments, devices, circuits, methods, etc., within the scope of the present disclosure.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are contemplated. For example, a region illustrated or described as square or rectangular may have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

As will be discussed in detail herein, it has been discovered that conventional passivation structures for power semiconductor devices that employ an organic passivation layer (e.g., polyimide) in an edge termination region of the device may have inherent problems associated therewith, including a phenomenon referred to as electrochemical migration. Electrochemical migration, which is similar to electromigration, involves atoms of a conductor (e.g., silver or copper) moving under the influence of a potential difference between separate conductors across the surface of an insulating material. Note that herein the term “insulating” is used broadly and encompasses dielectric materials/layers. Moisture and/or surface contamination are generally required for this reaction to occur. Atoms of silver, copper, or other conductor materials may dissolve in the presence of moisture (e.g., atmospheric humidity) to form an ionic aqueous solution that can be drawn toward a conductor of opposite charge, before effectively electroplating out on the surface of the insulating material. The plated silver or copper deposits form tree-like growths (called dendrites) that extend from one conductor across the surface of the insulating material. This migration of conductor atoms is often referred to as “creepage,” and the length of a path along which these conductor atoms travel is often referred to “creepage distance.” The dendrites grow until they bridge the surface between two such conductors, ultimately resulting in a short circuit. The above-described electrochemical migration may occur in power semiconductor devices because, for example, a silver sintering process is often used to attach a bottom terminal (e.g., drain terminal) of the semiconductor die to a base structure. When an electric potential is applied across the semiconductor device, silver ions may travel from the bottom terminal, along an interface between the device and its organic passivation layer, and create an electrical short between the bottom terminal and a top terminal of the semiconductor die. This phenomenon represents an important failure mechanism in power semiconductor devices.

A semiconductor device may include an active region, an edge termination region that is arranged along a perimeter of the active region, and a passivation structure that may form a die seal along the edge termination region. Pursuant to embodiments of the present disclosure, a passivation structure for a power semiconductor device is provided that is configured, using various techniques or combinations thereof as described herein, to increase creepage distance. The passivation structure may include one or more passivation layers configured in a manner that not only improves mechanical strength and adhesion of the passivation structure along the edge termination region, but increases creepage distance to thereby improve reliability of the semiconductor device.

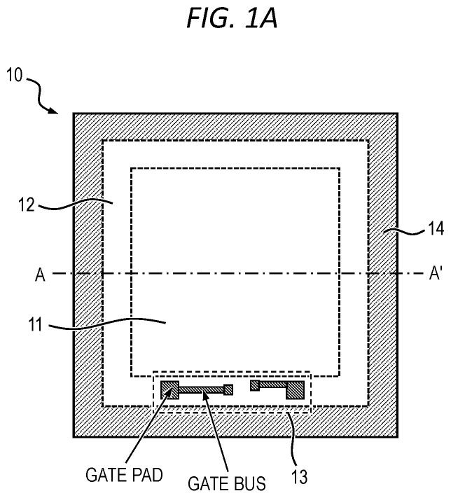

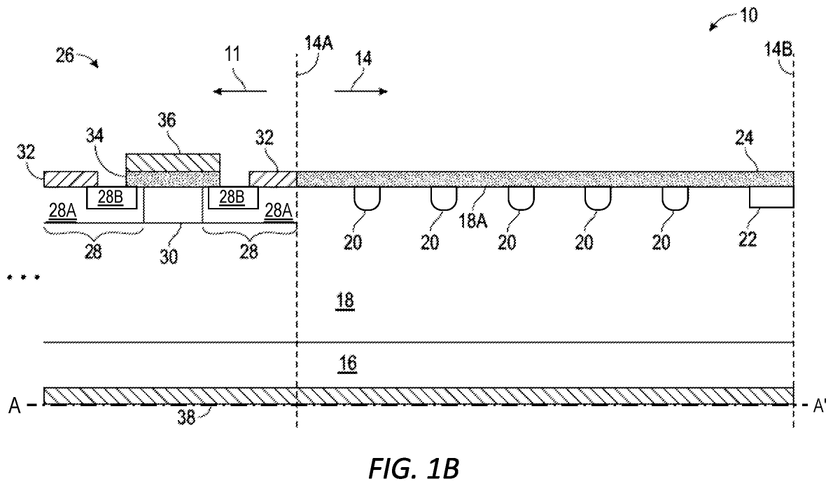

FIG. 1A is a plan view depicting a top surface of an exemplary semiconductor device 10 according to the present disclosure. The semiconductor device 10 includes an active region 11 and an inactive region 12. The inactive region 12 may include regions 13 where pads, buses or other structures are formed (e.g., gate pads and/or gate buses) without disposing any active devices under these structures, and an edge termination region 14 that extends around (i.e., surrounds) the active region 11 about a periphery (i.e., outside edge) of the semiconductor device 10. Depending on the particular application, the active region 11 may include one or more active semiconductor circuit elements or semiconductor device cells formed therein, such as, for example, one or more metal-oxide-semiconductor field-effect transistors (MOSFETs), diodes, Schottky diodes, junction barrier Schottky (JBS) diodes, PIN diodes, and/or insulated-gate bipolar transistors (IGBTs), among other circuit elements. The semiconductor device 10 may embody wide bandgap semiconductor devices, for example silicon carbide (SiC)-based devices. The edge termination region 14 may be configured to reduce a concentration of an electric field at the edges of the semiconductor device 10 in order to improve the performance thereof. For example, the edge termination region 14 may increase a breakdown voltage of the semiconductor device 10 and decrease a leakage current of the semiconductor device 10 over time. By way of example, the edge termination region 14 may include one or more guard rings, a junction termination extension (JTE), and combinations thereof.

FIG. 1B is a cross-sectional view depicting a portion of the exemplary semiconductor device 10 of FIG. 1A, taken along line A-A′, for embodiments where the semiconductor device 10 includes a MOSFET. While an illustrative MOSFET is described, the principles of the present disclosure are similarly applicable to other semiconductor devices listed above, including diodes, Schottky diodes, JBS diodes, PIN diodes, and IGBTs, among others. The semiconductor device 10 includes a substrate 16 and a drift region 18 on the substrate 16. In this illustrative embodiment, the substrate 16 may be doped with an n-type dopant (e.g., arsenic (As) or phosphorous (P)) at a prescribed doping concentration level, and the drift region 18 may be doped with an n-type dopant at a doping concentration level that is lower compared to that of the substrate 16; that is, the substrate 16 may be more heavily doped than the drift region 18. It is to be appreciated, however, that embodiments of the invention are not limited to an n-type substrate 16 or an n-type drift region 18. That is, the substrate 16 and/or drift region 18 may alternatively be doped with a p-type dopant (e.g., boron (B)) at a prescribed doping concentration level. Although shown as a single layer, the drift region 18 may embody one or more layers of a wide bandgap semiconductor material, such as, for example, SiC.

The substrate 16 may have a doping concentration between about 1×10¹⁷ cm⁻³ and 1×10²⁰ cm⁻³. In various embodiments, the doping concentration of the substrate 16 may be provided at any subrange between 1×10¹⁷ cm⁻³ and 1×10²⁰ cm⁻³. For example, the doping concentration of the substrate 16 may be between 1×10¹⁸ cm⁻³ and 1×10²⁰ cm⁻³, between 1×10¹⁹ cm⁻³ and 1×10²⁰ cm⁻³, between 1×10¹⁷ cm⁻³ and 1×10¹⁹ cm⁻³, between 1×10¹⁷ cm⁻³ and 1×10¹⁸ cm⁻³, and between 1×10¹⁸ cm⁻³ and 1×10¹⁹ cm⁻³.

The drift region 18 may have a doping concentration between 1×10¹⁴ cm⁻³ and 1×10¹⁸ cm⁻³. In various embodiments, the doping concentration of the drift region 18 may be provided at any subrange between 1×10¹⁴ cm⁻³ and 1×10¹⁸ cm⁻³. For example, the doping concentration of the drift region 18 may be between 1×10¹⁵ cm⁻³ and 1×10¹⁸ cm⁻³, between 1×10¹⁶ cm⁻³ and 1×10¹⁸ cm⁻³, between 1×10¹⁷ cm⁻³ and 1×10¹⁸ cm⁻³, between 1×10¹⁴ cm⁻³ and 1×10¹⁷ cm⁻³, between 1×10¹⁴ cm⁻³ and 1×10¹⁶ cm⁻³, between 1×10¹⁴ cm⁻³ and 1×10¹⁵ cm⁻³, between 1×10¹⁵ cm⁻³ and 1×10¹⁷ cm⁻³, between 1×10¹⁵ cm⁻³ and 1×10¹⁶ cm⁻³, and between 1×10¹⁶ cm⁻³ and 1×10¹⁷ cm⁻³.

With continued reference to FIG. 1B, an inside edge 14A of the edge termination region 14 is indicated by a vertical dashed line to delineate the edge termination region 14 from the active region 11 of the semiconductor device 10. An outside (i.e., peripheral) edge 14B of the edge termination region 14 may correspond with a peripheral edge of the semiconductor device 10. In the edge termination region 14, a number of guard rings 20 may be provided in the drift region 18. Specifically, the guard rings 20 may be provided adjacent or even directly adjacent to a top surface 18A of the drift region 18 opposite the substrate 16. The guard rings 20 may be formed by ion implantation and the implants used may include, for example, aluminum (Al), boron (B), or any other suitable p-type dopant when the drift region 18 is configured as an n-type layer. Each guard ring 20 forms a sub-region in the edge termination region 14 that has a doping type that is opposite a doping type of the drift region 18. In the present example, the drift region 18 is an n-type layer while the guard rings 20 are p-type sub-regions. However, the principles of the present disclosure apply equally to devices with opposite polarity configurations where the doping types as illustrated in FIG. 1B may be reversed. For illustrative purposes, five guard rings 20 are illustrated in FIG. 1B, although embodiments employing more guard rings 20 (e.g., six or more) or less guard rings 20 (e.g., four or less) are similarly contemplated. In various embodiments, the number of guard rings 20 may be five or more, or ten or more, or twenty or more, or in a range from five to twenty, or in a range from ten to twenty, depending on the application.

When the semiconductor device 10 operates in reverse blocking mode, the electric fields tend to concentrate much more heavily at the outside edge 14B of the edge termination region 14 than at the inside edge 14A of the edge termination region 14. In certain embodiments, a surface depletion protection region 22 may also be provided in the drift region 18 at the outside edge 14B of the edge termination region 14, proximate the upper surface 18A of the drift region 18. The surface depletion protection region 22 may have the same doping type as the drift region 18. In this manner, the surface depletion protection region 22 may prevent depletion at the top surface 18A of the drift region 18 in order to further improve the performance of the semiconductor device 10. In certain embodiments, the surface depletion protection region 22 is provided by implantation.

The surface depletion protection region 22 may have a doping concentration that is higher than the doping concentration of the drift region 18. In various embodiments, the surface depletion protection region 22 may have a doping concentration in a range from two times to 105 times the doping concentration of the drift region 18.

The guard rings 20 may have a doping concentration between 5×10¹⁶ cm⁻³ and 1×10²¹ cm⁻³. In various embodiments, the doping concentration of the guard rings 20 may be provided at any subrange between 5×10¹⁶ cm⁻³ and 1×10²¹ cm⁻³. For example, the doping concentration of the guard rings 20 may be between 5×10¹⁸ cm⁻³ and 1×10²¹ cm⁻³, between 5×10¹⁹ cm⁻³ and 1×10²¹ cm⁻³, between 5×10²⁰ cm⁻³ and 1×10²¹ cm⁻³, between 5×10¹⁶ cm⁻³ and 1×10²⁰ cm⁻³, between 5×10¹⁶ cm⁻³ and 1×10¹⁹ cm⁻³, and between 5×10¹⁶ cm⁻³ and 1×10²⁰ cm⁻³.

A passivation layer 24 may be provided on the top surface 18A of the drift region 18 opposite the substrate 16 to passivate the top surface 18A of the drift region 18. The passivation layer 24 may embody one or more layers of insulating materials of any suitable material, for example one or more layers of oxide and/or nitride-based dielectric layers. In certain embodiments, the passivation layer 24 may embody a multilayer structure that includes, for example, one or more of a field oxide layer, one or more intermetal dielectric layers, and a top insulating layer.

As discussed above, the active region 11 may include one or more active semiconductor circuit elements. In the exemplary semiconductor device 10 shown in FIG. 1B, the active region 11 includes at least one MOSFET cell 26, for example a SiC-based MOSFET where the drift region 18 embodies one or more layers of SiC. The MOSFET cell 26 includes the substrate 16 and the drift region 18. A number of junction implants 28 are provided in the drift region 18, and specifically in the top surface 18A of the drift region 18 opposite the substrate 16. The junction implants 28 include a first well region 28A, having a doping type that is opposite that of the drift region 18 (e.g., p-type), and a second well region 28B, having a doping type that is the same as the drift region 18 (e.g., n-type). The junction implants 28 may be separated from one another by a JFET region 30. The JFET region 30 has the same doping type as that of the drift region 18 and a higher doping concentration than that of the drift region 18. A source contact 32 is provided over each one of the junction implants 28 on the top surface 18A of the drift region 18 opposite the substrate 16 such that the source contact 32 electrically contacts a portion of the first well region 28A and the second well region 28B.

A gate dielectric layer 34 (e.g., a silicon oxide layer) is provided on the top surface 18A of the drift region 18 opposite the substrate 16 over the JFET region 30 and a portion of each one of the junction implants 28 such that the gate dielectric layer 34 partially overlaps each one of the second well regions 28B in a vertical direction on opposite sides of the JFET region 30. A gate contact 36 is provided on the gate dielectric layer 34. A drain contact 38 is provided on a surface of the substrate 16 opposite the drift region 18. The MOSFET cell 26 may be tiled (i.e., repeated) across the active region 11 or tiled in a desired pattern with one or more other semiconductor devices (e.g., diodes) to provide a desired functionality.

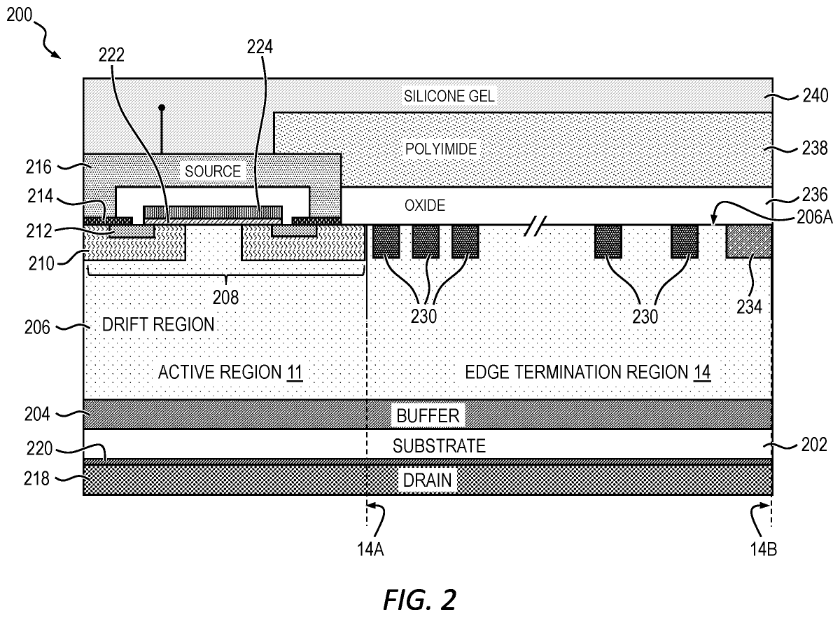

Often, power semiconductor devices are passivated at the edge termination region using an organic passivation layer. This organic passivation layer may be formed of, for example, polyimide. An illustrative passivation structure is shown in FIG. 2. Specifically, FIG. 2 is a cross-sectional view depicting at least a portion of an exemplary power semiconductor device 200 including a passivation structure employing an organic passivation layer. The semiconductor device 200 includes a substrate 202, a buffer layer 204 on the substrate 202, and a drift region 206 on the buffer layer 204.

As in the semiconductor device 10 shown in FIGS. 1A and 1B, the semiconductor device 200 includes an active region 11 and an edge termination region 14 extending around (i.e., surrounding) the active region 11 about a periphery (i.e., outside edge) of the semiconductor device 10 when viewed in a plan view. An inside edge 14A of the edge termination region 14 is indicated by a vertical dashed line to delineate the edge termination region 14 from the active region 11 of the semiconductor device 200. An outside edge 14B of the edge termination region 14 may correspond with a peripheral edge of the semiconductor device 200.

In the exemplary semiconductor device 200 shown in FIG. 2, the active region 11 includes at least one MOSFET cell 208, for example a SiC-based MOSFET where the drift region 206 embodies one or more layers of SiC. The MOSFET cell 208 includes the substrate 202 and the drift region 206. A number of junction implants are provided in the drift region 206, specifically in a top surface 206A of the drift region 206 opposite the substrate 202. The junction implants may include a first well region 210, having a doping type that is opposite that of the drift region 206 (e.g., p-type), and a second well region 212, having a doping type that is the same as the drift region 206 (e.g., n-type). As multiple unit cell MOSFETs are provided, the junction implants 210, 212 of adjacent MOSFET unit cells are laterally separated from one another. The portions of the drift region 206 that are disposed between the laterally separated junction implants 210, 212 are referred to as JFET regions.

A source contact 214 is provided over each of the junction implants 210, 212 on the top surface 206A of the drift region 206 such that the source contact 214 electrically contacts a portion of the first well region 210 and the second well region 212. A source electrode 216 may be provided for electrically connecting the laterally separated junction implants 210, 212. A drain contact 218 is provided on a back surface of the substrate 202 opposite the drift region 206. A conductive layer 220 may be disposed between the drain contact 218 and the back surface of the substrate 202 to reduce electrical resistance between the drain contact 218 and the substrate 202, serving as a drain region of the MOSFET cell 208.

A gate dielectric layer 222 (e.g., a silicon oxide layer) is provided on the top surface 206A of the drift region 206 opposite the substrate 202 over the portion of the drift region 206 separating the junction implants 210, 212. The gate dielectric layer 222 may be configured to partially overlap each one of the second well regions 212 in a vertical direction (i.e., perpendicular to the top surface 206A of the drift region 206). A gate contact 224 is provided on the gate dielectric layer 222. The MOSFET cell 208 may be tiled (i.e., repeated) across the active region 11 or tiled in a desired pattern with one or more other semiconductor devices (e.g., diodes, etc.) to provide a desired functionality.

In the edge termination region 14, a plurality of guard rings 230 may be provided in the drift region 206, proximate the top surface 206A of the drift region 206 opposite the substrate 202. Each of the guard rings 230 forms a sub-region in the edge termination region 14 that has a doping type that is opposite a doping type of the drift region 206. In the present example, assuming the drift region 206 is an n-type layer, the guard rings 230 are p-type sub-regions. However, the principles of the inventive concept apply equally to devices with opposite polarity configurations where the doping types as illustrated in FIG. 2 may be reversed. In certain embodiments, a surface depletion protection region 234 may also be provided in the drift region 206 proximate the outside (i.e., peripheral) edge 14B of the edge termination region 14, and proximate the upper surface 206A of the drift region 206. The surface depletion protection region 234 may have the same doping type as the drift region 206 but at a higher doping concentration than that of the drift region 206.

The semiconductor device 200 may further include a passivation structure formed on the top surface 206A of the drift region 206 opposite the substrate 202. In this example, the passivation structure includes an oxide layer 236 extending horizontally along the top surface 206A of the drift region 206 (i.e., in an x-axis and/or a y-axis direction, parallel to the top surface 206A of the drift region 206) in the edge termination region 14. The oxide layer 236 may extend partially into the active region 11 such that an end of the oxide layer 236, opposite the peripheral edge 14B of the edge termination region 14, abuts the source electrode 216 in the active region 11.

The passivation structure further includes a polyimide (or other polymer) layer 238 formed on the oxide layer 236. An end of the polyimide layer 238 opposite the peripheral edge 14B of the edge termination region 14 may extend onto a top surface of a portion of the source electrode 216 in the active region 11. In some embodiments, a hard passivation layer (e.g., silicon nitride), not explicitly shown, may be included between the oxide layer 236 and the polyimide layer 238, coincident with the polyimide layer 238. A cross-sectional thickness of the polyimide layer 238 may be about 4 μm-10 μm, although embodiments are not limited thereto. A layer of silicone gel 240 may be formed over a top surface of the semiconductor device 200, including over a top surface of the polyimide layer 238 and exposed surfaces of the active region 11.

Power semiconductor devices are generally deployed in either plastic packages, where usually one or two devices are encapsulated in molding compound, or power modules, in which several power devices with a given topology are integrated into a single case filled with silicone gel. The silicone gel may be applied after wire bonding has been completed. In plastic packages, the penetration of moisture is very slow when compared to power modules, since the molded plastic offers a higher level of moisture protection than silicone gel. In the case of power module packages, however, moisture penetration toward active areas of the devices may occur more rapidly due at least in part to the presence of the silicone gel. A high-voltage temperature humidity bias (HV-THB) test is a device test which can be applied to power devices both in plastic packages and power modules. During HV-THB testing, the devices undergo triple stress due to the simultaneous application of high-voltage reverse bias, high-humidity and temperature for a pre-determined period of time.

It is well-known that the penetration of moisture has a significant influence on the reliability of semiconductor devices and even a small change in relative humidity can have a large effect on median time to failure of a semiconductor device. There is a variety of different deterioration mechanisms attributable to moisture intrusion in a semiconductor device, but one of the most common failure mechanisms occurring in electronic devices under high humid conditions is electrochemical migration, which generally involves corrosion of a metal electrode (e.g., metal corrosion), metal migration, and metal redeposition on another electrode, as previously described. By formation of a closed nanoscale water layer (i.e., an electrolytic solution layer) on an insulating surface (e.g., dielectric) linking two adjacent conductors at different voltage potentials, a corrosion cell can build up. The process starts with the decomposition of water and the movement of the resulting conductor ions according to their respective charge and an applied electric field.

Under the influence of the applied electric field, the anodically dissolved conductor ions will migrate towards a negatively charged cathode. There they are deposited and recombine to neutral conductor atoms if the applied voltage exceeds the sum of the anodic and cathodic standard potential in aqueous solution. The corrosive current is, thus, carried by electrons in the metallization and by ions in the aqueous solution. Because the conductor ions move in the direction of highest potential to lowest potential, they will end up at inevitable field tips on the cathode side. As previously explained, these conductor ions will form dendrites which deteriorate the insulation capability of the junction termination and eventually lead to device failure.

The passivation structure shown in FIG. 2 may be sufficient in many cases, but starts to exhibit weaknesses which can result in device failure, particularly when the passivation structure is used in silver (Ag)-sintered applications in combination with the silicone gel 240, or other elastomers (e.g., rubber, polyurethanes, etc.). In particular, it has been discovered that silver ions originating from the silver sintering of the drain contact 218 to a sub-mount (e.g., leadframe, etc.) can migrate from a high voltage potential to a low voltage potential around the edge of the chip, and will creep along the mechanically weakest interface that is present in the semiconductor device 200; in this case, the interface between the polyimide layer 238 and the silicone gel 240 (which may be referred to herein as a gel-polyimide interface).

Specifically, the silicone gel 240 attracts moisture, essentially creating a water pathway around the semiconductor device 200. The water interacts favorably with silver to form an aqueous solution of silver ions. The silver ions (from drain and/or source silver sintering) can travel significant distances throughout the semiconductor device 200, generally along a path from a high voltage potential to a low voltage potential, using the water pathway created by the silicone gel 240. Assuming the drain contact 218 is at a higher voltage potential relative to the source contact 216, silver ions will travel along a peripheral edge (e.g., right side in FIG. 2) of the semiconductor device 200, through the gel-polyimide interface 240/238, to the source contact 216, thereby creating a short circuit.

The amount of time it takes for the silver (or another conductor) ions from the drain contact 218 to reach the source contact 216, which may be referred to herein as “creepage time,” will be a function of various factors, including the moisture/humidity level in the semiconductor device 200. However, a predominant factor in determining the creepage time may be the length of the path (i.e., “creepage path”) along which the conductor ions must travel between two conductors of differing voltage potentials; the term “creepage path may be used synonymously herein with the term “creepage distance.” In accordance with embodiments of the invention, the likelihood of semiconductor device failure attributable to electrochemical migration can be reduced by increasing a length of the creepage path in the device.

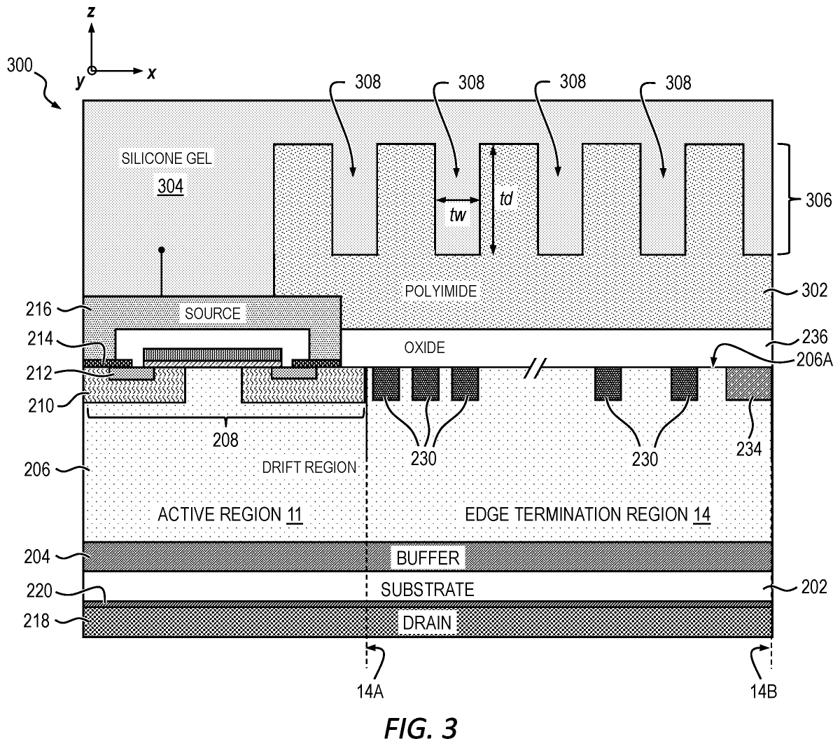

FIG. 3 is a cross-sectional view depicting at least a portion of an exemplary power semiconductor device 300 comprising a passivation structure that is defined on the semiconductor die during the fabrication process, according to one or more embodiments of the present disclosure. The passivation structure includes an organic passivation layer configured to increase a creepage path length (i.e., “creepage distance”) in the semiconductor device 300. The creepage path may be defined as the path where failure by “tracking” (i.e., the formation of a conductive path between charged conductors across the surface of an insulator) or by electrochemical migration is most likely to occur.

As previously stated, creepage distance may be defined as the distance of a path along which conductor (e.g., silver) ions must travel before device failure occurs. Increasing creepage distance results in a proportional decrease in creepage time, which is an important objective for meeting certain device operating specifications, as may be measured using industry-standard tests, such as, for example, THB 80 (temperature, humidity, bias at eighty percent of rated drain voltage test), HV-THB (high-voltage temperature humidity bias test), HV-H³TRB (high voltage-high humidity high temperature reverse bias test), and/or other semiconductor reliability tests.

The semiconductor device 300 may be similar to the illustrative semiconductor device 200 shown in FIG. 2, except for the configuration of the passivation structure. Like reference numbers refer to corresponding elements throughout the figures which have already been described in detail above, and therefore a detailed description of repeated elements will not be presented herein. With reference to FIG. 3, the semiconductor device 300 includes a passivation structure comprising a polyimide (or other polymer) layer 302 formed on the oxide layer 236 in the edge termination region 14. The polyimide layer 302 may comprise, for example, Kapton® (a registered trademark of Dupont Electronics, Inc.), although embodiments are not limited thereto. In one or more embodiments, the polyimide layer 302 extends over a majority of the top surface 206A of the drift region 206 in the edge termination region 14 (e.g., greater than about 50 percent of the edge termination region 14). As in the semiconductor device 200 of FIG. 2, an end of the polyimide layer 302 opposite the peripheral edge 14B of the edge termination region 14 may extend onto a portion of the top surface of the source electrode 216 in the active region 11 of the semiconductor device 300. In some embodiments, a hard passivation layer (e.g., silicon nitride), not explicitly shown, may be included between the oxide layer 236 and the polyimide layer 302, coincident with the polyimide layer 302. A layer of silicone gel 304 (or another elastomer) may be formed over a top surface of the semiconductor device 300, including over a top surface of the polyimide layer 302 and exposed surfaces of the active region 11. The silicone gel 304 may be applied to the semiconductor device 300 after wire bonding has been completed.

In contrast to the polyimide layer 238 shown in FIG. 2, which is formed having a planar (i.e., flat) top surface, an upper portion 306 of the polyimide layer 302 in the semiconductor device 300 is configured to have a corrugated (i.e., trenched, grooved, ribbed, etc.) or stepped profile to thereby increase a creepage distance by increasing an overall length of the interface between the silicone gel 304 and the polyimide layer 302. This corrugated upper portion 306 of the polyimide layer 302 may be created, in one or more embodiments, by forming one or more trenches (or similar openings) 308 in the upper portion 306 of the polyimide layer 302 extending vertically (i.e., in a z-axis direction, perpendicular to the top surface 206A of the drift region 206) into the polyimide layer 302. The trenches 308 may be defined in between upwardly-extending pillars that are part of the polyimide layer 302. While these pillars are shown in FIG. 3 as having rectangular cross-sections, it will be appreciated that embodiments of the invention are not limited thereto. For example, in other embodiments the pillars may have rounded upper surfaces or beveled upper corners as a result of an etching process used to form the trenches 302. The trenches 308 are spaced apart from one another in an x-axis direction and running across the top surface of the polyimide layer 302 in a y-axis direction which intersects the x-axis direction. In this example, the polyimide layer 302 is shown as including five trenches, although it is to be appreciated that embodiments are not limited to any specific number of trenches 308; that is, fewer (e.g., four or less) trenches 308 or more (e.g., six or more) trenches 308 may be formed in the polyimide layer 302. The trenches 308 may be equally or non-equally spaced apart from one another.

In some embodiments, the trenches 308 may be formed in the polyimide layer 302 using a photosensitive polyimide material (e.g., a negative-acting photo-definable polyimide) which is blanket-deposited over the wafer, or deposited on a select portion of the upper surface of the wafer (including the oxide layer 236), using a known deposition process (e.g., chemical vapor deposition (CVD), atomic layer deposition (ALD), etc.). The polyimide layer 302 is then selectively patterned using a standard photolithography process, followed by an etching process to form the trenches 308, thereby providing the corrugated upper portion 306. In an anisotropic etching process, an etchant or solvent can be used to selectively remove the polyimide material in select locations (i.e., areas of the polyimide material that have not been crosslinked due to exposure to ultraviolet radiation), thus forming the trenches 308. Suitable etching processes for forming the trenches 308 may include, for example, plasma (dry) etching, reactive ion etching (RIE), wet etching, etc. After etching, pillars of polyimide material will remain between adjacent trenches 308, with the pillars and trenches 308 forming peaks and valleys, respectively, of the corrugated upper portion 306 of the polyimide layer 302.

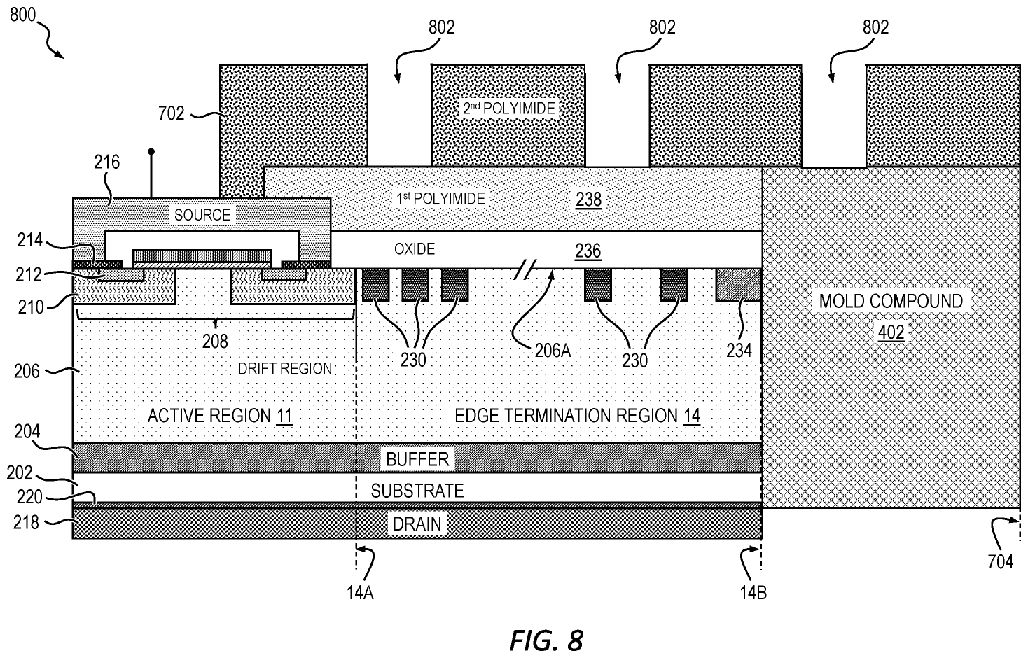

Although shown as a homogeneous structure, it is to be appreciated that in some embodiments, the polyimide layer 302 may be formed as a multilayer structure. Moreover, the corrugated upper portion 306 may be formed as a second polyimide layer (e.g., in a separate deposition step from the rest of the polyimide layer 302). When the corrugated upper portion 306 is formed as a second polyimide layer (see, e.g., FIG. 8), the corrugated upper portion 306 may, optionally, comprise a different material than the polyimide layer 302.

Although the trenches 308 are shown as having substantially vertical sidewalls, it is to be appreciated that the shape of the trenches 308 is not limited thereto. As non-limiting examples, in some embodiments, the sidewalls of the trenches 308 may be sloped (e.g., either inward or outward sloping). In other embodiments, the trenches may be formed as rounded openings. In still other embodiments, the sidewalls of the trenches 308 may be vertical and the bottom surface of the trenches may be rounded (e.g., concave). It is be understood that embodiments of the present disclosure are not limited to any particular shape or dimensions of the trenches 308. Furthermore, the pillars of polyimide material between the trenches 308 may not necessarily be coplanar (i.e., of the same height); that is, at least two polyimide pillars may be at different vertical heights (i.e., in the z-axis direction) relative to one another.

A length of the interface between the silicone gel 304 and the polyimide layer 302 may be controlled as a function of a depth, td, and/or a frequency (i.e., number) of the trenches 308 in the polyimide layer 302. The deeper the trenches 308 and/or the greater number of trenches 308 in the polyimide layer 302, the greater the length of the gel-polyimide interface (all other factors being the same), and thus the greater the creepage distance. However, a trade-off may exist between the depth of the trenches 308 and a horizontal width, tw (i.e., in a direction parallel to the top surface 206A of the drift region 206), of the trenches 308. Deeper trenches generally require a greater width, due at least in part to limitations of the etching process used to form the trenches. Hence, deeper trenches 308 may necessitate a reduced number of trenches that are used. The number of corrugation steps in the upper portion 306 of the polyimide layer 302 may be limited only by a resolution of the photolithography process, but are likely constrained to have an aspect ratio (trench depth td to trench width tw) of about 1:1 to 2:1. In one or more embodiments, the depth td of the trenches 308 (and thus a vertical height of the upper portion 306 of the polyimide layer 302) may be about 4 μm to 100 μm, although embodiments are not limited thereto. In other embodiments, the depth td of the trenches 308 may be about 4 μm to 80 μm, about 20 μm to 100 μm, about 40 μm to 80 μm, about 4 μm to 20 μm, about 10 μm to 80 μm, about 10 μm to 40 μm, about 20 μm to 60 μm, about 30 μm to 100 μm, or about 50 μm to 100 μm. The trenches 308 may all have the same depth td or some trenches 308 may have different depths td than other trenches 308.

In the semiconductor device 200 shown in FIG. 2, silver ions will migrate from the drain contact 218, up the peripheral edge 14B of the semiconductor device 200, across the flat interface between the polyimide layer 238 and the silicone gel 240, and to the source electrode 216. By comparison, in the semiconductor device 300 shown in FIG. 3, silver ions will migrate from the drain contact 218, up the peripheral edge 14B of the semiconductor device 300, across the corrugated upper portion 306 of the polyimide layer 302 forming the interface between the silicone gel 304 and the polyimide layer 302, and to the source electrode 216. Since the creepage distance (i.e., the overall length of the creepage path) that the conductor ions must travel is substantially greater in the semiconductor device 300 compared to the semiconductor device 200 of FIG. 2, the creepage time for the semiconductor device 300 of FIG. 3 will be much greater than that of the semiconductor device 200 of FIG. 2. Thus, in the embodiment of the semiconductor device 300 shown in FIG. 3, creepage distance effectively becomes a design parameter that can be controlled, and thus the creepage distance is no longer constrained by the termination length and die side thickness.

As noted above, the passivation structure comprising the polyimide (or other polymer) layer 302 that is provided on the oxide layer 236 may be formed during wafer level processing. In other words, a semiconductor wafer may be formed that includes a plurality of semiconductor die, each of which may have its own edge termination region 14. The passivation structure may be formed on each of the semiconductor die before the wafer is singulated into individual semiconductor die. As discussed above, one or more openings may be formed in the top surface of the first polymer layer, where these openings extend vertically, perpendicular to a top surface of the drift region, at least partially into the first polymer layer. Such openings may be formed in portions of the first polymer layer that are on the edge termination regions of the individual un-singulated semiconductor die.

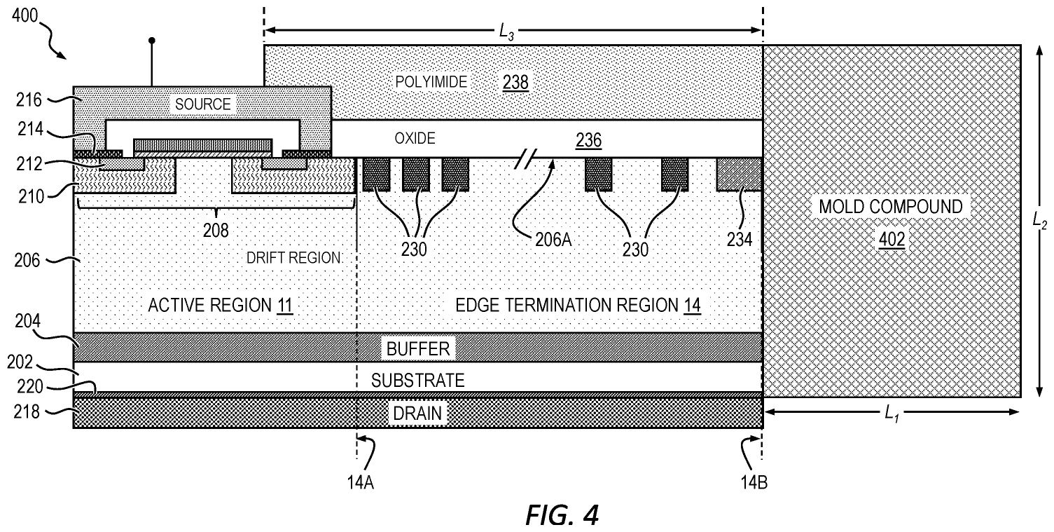

Numerous variations are contemplated for controlling the creepage distance in a semiconductor device, in accordance with embodiments of the inventive concept. By way of example only and without limitation or loss of generality, FIGS. 4-8 show various configurations of passivation structures for increasing creepage distance compared to conventional passivation structures, according to embodiments of the present disclosure. Specifically, FIG. 4 is a cross-sectional view illustrating at least a portion of an exemplary semiconductor device 400 including a passivation structure configured to increase creepage distance in the semiconductor device, according to an alternative embodiment of the present disclosure.

With reference to FIG. 4, the semiconductor device 400 may include the polyimide layer 238 formed on the oxide layer 236. In some embodiments, a cross-sectional thickness of the polyimide layer 238 may be about 4 μm-10 μm, although embodiments are not limited thereto. The semiconductor device 400 further includes a mold compound 402 disposed on the peripheral edge 14B of the of the edge termination region 14 laterally adjacent to the drift region 206. The mold compound 402 includes a bottom surface that may be coplanar with a top surface of the drain contact 218 (an interface between the drain contact 218 and the conductive layer 220), and a top surface that may be coplanar with a top surface of the polyimide layer 238. The mold compound 402 may comprise, for example, an epoxy mold compound (EMC) or other encapsulant (e.g., a silicone, polyurethane, chloroprene, butyl, polybutadiene, neoprene, natural rubber, isoprene, synthetic rubber or phenolic hardener encapsulant).

To further increase the creepage distance in the semiconductor device 400, the top surface of the polyimide layer 238 may be patterned to form corrugations, in a manner consistent with the configuration of the polyimide layer 302 shown in FIG. 3. Thus, the overmold technique of FIG. 4 may be combined with the polyimide layer corrugation techniques shown in FIG. 3 to further increase the creepage distance.

Using this approach, conductor ions (e.g., from the drain contact 218), in order to reach the source electrode 216, must travel horizontally across a bottom surface of the mold compound 402 (length L₁), vertically up a side surface of the mold compound 402, horizontally across a top surface of the mold compound 402, and horizontally across the top surface of the polyimide layer 238. The total creepage distance in this case would be 2L₁+L₂+L₃, where L₁ is a length of the top or bottom surface of the mold compound 402, L₂ is a length of the side edge of the mold compound 402, and L₃ is a length of the top surface of the polyimide layer 238. Compared to the passivation structure shown in FIG. 2, the creepage distance in the semiconductor device 400 of FIG. 4 would be increased by 2L₁.

Unlike the passivation structure included in the illustrative semiconductor device 300 shown in FIG. 3, which is formed at a wafer level during the die fabrication process, the passivation structure in the illustrative semiconductor device 400 of FIG. 4 may be formed post-dicing using wafer reconstruction techniques. During wafer reconstruction, separated (i.e., diced) die may be placed on a wafer or other carrier and then subjected to an overmolding process. The subsequent die may then be picked off (i.e., separated) and utilized in case modules, bridging a gap between overmolded modules and gel-filled modules. The realized product in this embodiment would be a die, with an additional layer of mold compound attached to the sides (e.g., peripheral edge 14B) of the die, as shown in FIG. 4.

Many conventional semiconductor packages include mold compounds as packaging. However, in these conventional devices the mold compound covers substantially the entire semiconductor die and extends over the active region of the semiconductor die to provide environmental protection to the semiconductor die. In sharp contrast, in the semiconductor device of FIG. 4 the mold compound 402 is only provided in the termination region of the device and does not extend over the active region as the mold compound is provided for purposes of increasing the creepage distance as opposed to providing environmental protection. In addition, the mold compound 402 is applied before the semiconductor die is mounted on a lead frame and/or before bond wires are connected to the semiconductor die, since the mold compound is not used as protective packaging but instead is provided to increase the creepage distance. The mold compound may extend at least part of the way around the edge termination region when viewed in plan view, and typically will extend all of the way around the edge termination region when viewed in plan view.

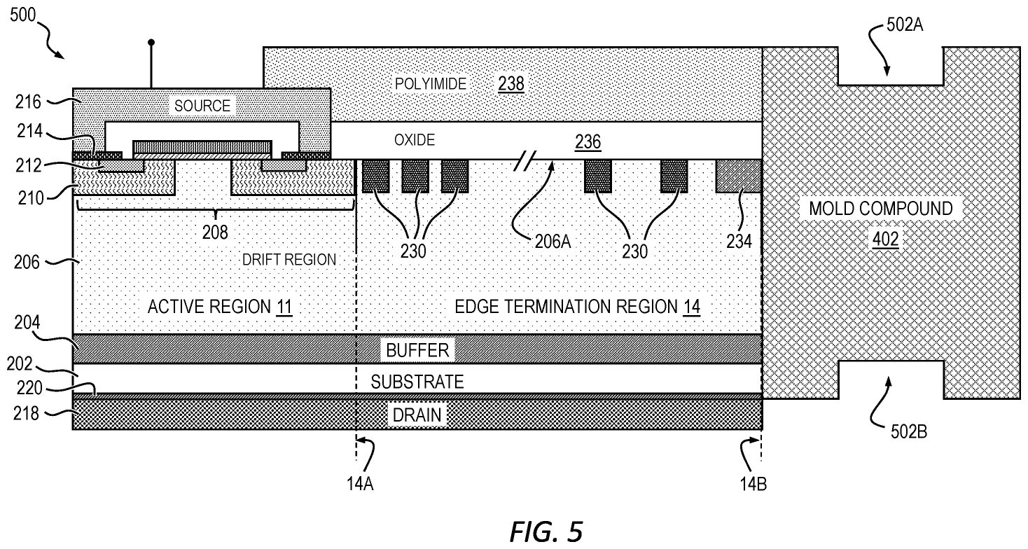

In one or more embodiments, the surface corrugation techniques previously described in conjunction with FIG. 3 can be combined with the overmold techniques utilized for the illustrative semiconductor device 400 shown in FIG. 4 to further increase creepage distance. For example, FIG. 5 is a cross-sectional view illustrating at least a portion of an exemplary semiconductor device 500 including a passivation structure employing a corrugated overmold structure configured to further increase creepage distance in the semiconductor device, according to one or more embodiments of the present disclosure. The semiconductor device 500 is similar to the illustrative semiconductor device 400 shown in FIG. 4, with the addition of trenching of the top and/or bottom surfaces of the mold compound 402.

Specifically, with reference to FIG. 5, a top surface of the mold compound 402 may include one or more trenches 502A formed therein, and/or a bottom surface of the mold compound 402 may include one or more trenches 502B formed therein, each of the trenches 502A, 502B extending vertically into the mold compound 402. Although the semiconductor device 500 is shown having only one trench 502A formed in the top surface of the mold compound 402 and only one trench 502B formed in the bottom surface of the mold compound 402, it is to be appreciated that embodiments are not limited thereto, and that more than one trench 502A (e.g., two or more) may be formed in the top surface and/or more than one trench 502B (e.g., two or more) may be formed in the bottom surface of the mold compound 402. The mold compound 402, like the mold compound 402 shown in FIG. 4, may comprise an epoxy mold compound, although embodiments are not limited thereto.

The trenches 502A, 502B form a corrugated top and/or bottom surface of the mold compound 402 which further increases the linear distance along the top and/or bottom surface, respectively, that conductor ions from the drain contact 218 must travel in order to reach the source electrode 216, thereby increasing creepage time. Using this corrugation technique, the creepage distance can be increased as a function of a depth and/or number of the trenches in the top surface and/or bottom surface of the mold compound 402. In comparison to the creepage distance for the semiconductor device 400 of FIG. 4, the addition of the trenches 502A and/or 502B in the top and/or bottom surfaces, respectively, of the mold compound 402 will increase the distance L₁, thus increasing the overall creepage distance and creepage time of the semiconductor device 500 accordingly.

In other embodiments (not explicitly shown), the techniques used to provide a corrugated top surface of the polyimide layer 238 described in conjunction with FIG. 3 may be similarly used in addition to, or in place of, the corrugated mold compound 402 to provide a corrugated top surface of the polyimide layer 238 in illustrative semiconductor device 500 shown in FIG. 5. This added corrugation will further increase the overall path length (e.g., by increasing the distance L₃ shown in FIG. 4) that the conductor ions must travel before reaching the source electrode 216, thereby increasing creepage distance and creepage time.

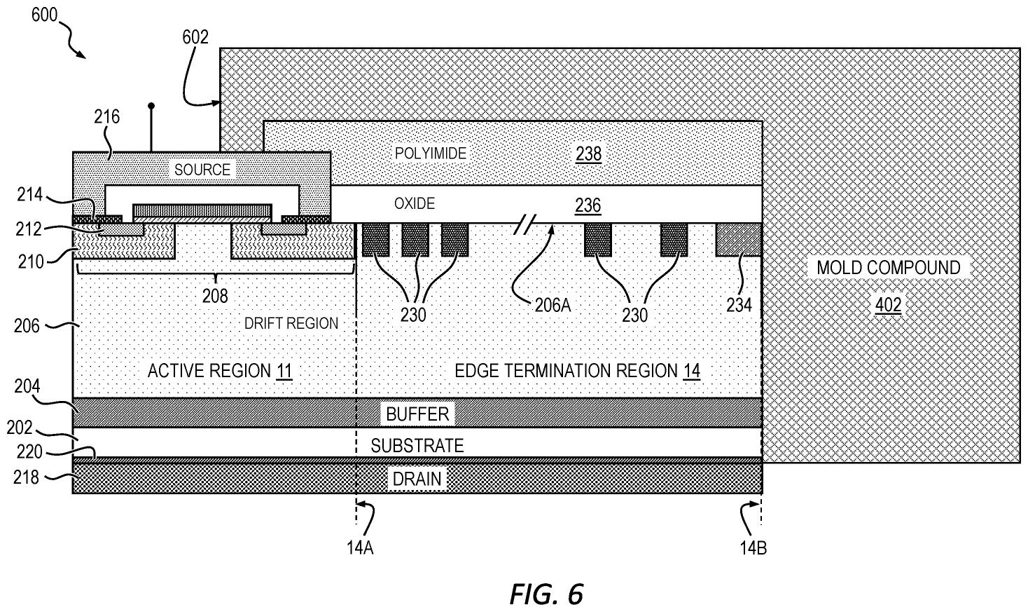

In accordance with one or more other embodiments, a shaped top encapsulation structure may allow for the mold compound (402 in FIGS. 4 and 5) to be wrapped over at least a portion of a top surface of the die. For example, FIG. 6 is a cross-sectional view depicting at least a portion of an exemplary semiconductor device 600 including a passivation structure comprising a shaped top encapsulation structure that allows the mold compound to encapsulate the die edges and top surface, according to one or more embodiments of the present disclosure.

With reference to FIG. 6, the semiconductor device 600 includes a passivation structure that comprises the mold compound 402 formed on the peripheral edge 14B of the of the edge termination region 14. The mold compound 402 extends vertically along the peripheral edge 14B (e.g., conformally covering the peripheral edge 14B) and onto the top surface of the polyimide layer 238. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. In this exemplary embodiment, the mold compound 402 covers an outside (i.e., peripheral) edge and at least a portion of the top surface of the polyimide layer 238. The term “covers” (or “cover” or “covering,” or like terms), as may be used herein, is intended to broadly refer to a material, layer or structure being on or over another material, layer or structure, but does not require the material, layer or structure to entirely cover the other material, layer or structure. An end 602 of the mold compound 402, opposite the peripheral edge 14B of the semiconductor device 600, may extend onto a portion of the top surface of the source electrode 216 in the active region 11 to cover an edge of the polyimide layer 238 while leaving at least a portion of the source electrode 216 exposed to allow electrical connection to the source electrode 216. The mold compound 402 used in the illustrative semiconductor device 600 depicted in FIG. 6, like the mold compound 402 shown in FIGS. 4 and 5, may comprise an epoxy mold compound, although embodiments are not limited thereto.

With the passivation structure configured in the manner shown in FIG. 6, conductor ions moving from the drain contact 218 to the source electrode 216 (assuming the drain contact is at a higher potential relative to the source electrode) must travel horizontally across a bottom surface of the mold compound 402, vertically up a side surface of the mold compound 402, horizontally across a top surface of the mold compound 402 (which may be greater than the distance across the top surface of the polyimide layer 238), and eventually reaching the source electrode 216. Compared to the passivation structure shown in FIG. 5, the creepage distance in the semiconductor device 600 of FIG. 6 would be greater.

It is to be understood that the mold compound 402 need not extend entirely over the edge termination region 14. For example, in some embodiments, the mold compound 402 may be configured to extend horizontally across a portion of the top surface of the polyimide layer 238, with the end 602 of the mold compound 402 disposed on the top surface of the polyimide layer 238 between the inside edge 14A and the peripheral edge 14B of the edge termination region 14. In some embodiments, the mold compound 402 is configured to cover a majority of the edge termination region 14 (e.g., about 50 percent or more).

In an alternative embodiment, in a manner consistent with the passivation structure shown in FIG. 5, the top surface and/or bottom surface of the mold compound 402 may be corrugated to further increase the path length along which conductor ions must travel between the drain contact 218 and the source electrode 216. Although not explicitly shown in FIG. 6, corrugation of the top surface and/or bottom surface of the mold compound 402 may be achieved by forming one or more trenches from a corresponding top and/or bottom surface of the mold compound 402 and extending vertically into the mold compound 402. In some embodiments, the trenches may extend through the mold compound 402 and partially into the underlying polyimide layer 238. Using this corrugation technique, the creepage distance can be increased as a function of a depth and/or number of the trenches in the top surface of the mold compound 402.

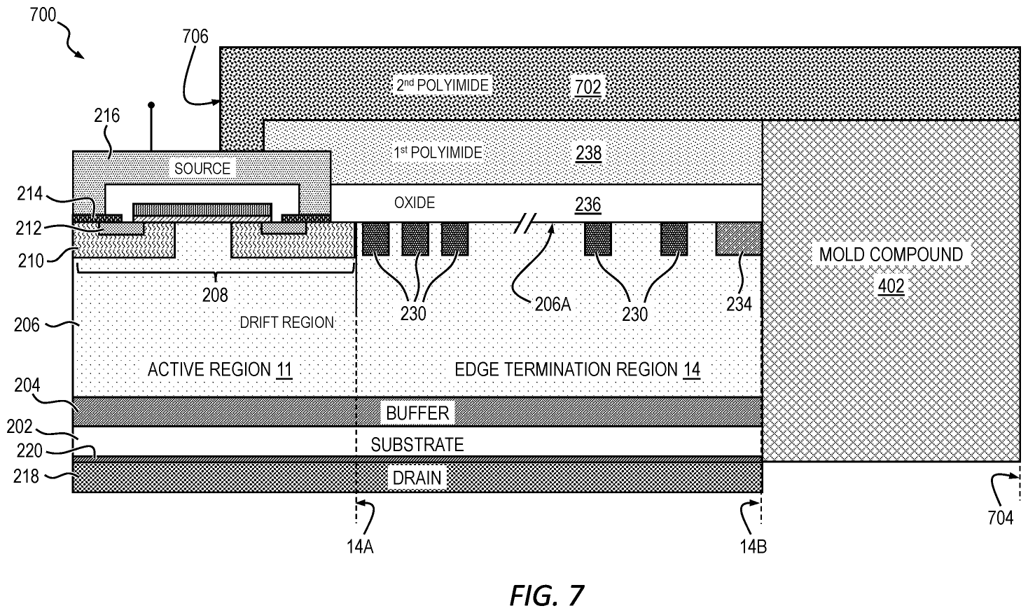

As a variation on the illustrative embodiment of the semiconductor device 400 shown in FIG. 4, FIG. 7 is a cross-sectional view depicting at least a portion of an exemplary semiconductor device 700 including a passivation structure comprising multiple polyimide layers, according to one or more embodiments of the present disclosure. Specifically, in the semiconductor device 700, the mold compound 402 may be configured having a top surface that is coplanar with the top surface of the polyimide layer 238, which will be referred to for this illustrative embodiment as a first polyimide layer.

The passivation structure in the semiconductor device 700 further includes at least a second polyimide layer 702 over the mold compound 402 and the first polyimide layer 238. The second polyimide layer 702 may extend horizontally from an outer edge 704 of the semiconductor device 700, across the respective top surfaces of the mold compound 402 and first polyimide layer 238. The second polyimide layer 702 may extend partially into the active region 11, such that an end 706 of the second polyimide layer 702, opposite the outer edge 704 of the semiconductor device 700, is disposed on a portion of the top surface of the source electrode 216. In this manner, the second polyimide layer 702 may cover an edge of the first polyimide layer 238 opposite the peripheral edge 14B of the edge termination region 14. A cross-sectional thickness of the first polyimide layer 238 may be about 4 μm-10 μm, although embodiments are not limited thereto. A cross-sectional thickness of the second polyimide layer 702 may be greater than that of the first polyimide layer 238, although embodiments are not limited to any specific thicknesses of the first polyimide layer 238 or second polyimide layer 702. Furthermore, although the exemplary semiconductor device 700 is shown as having two polyimide layers 238, 702, it is to be appreciated that more than two polyimide layers (e.g., three or more polyimide layers) may similarly be employed, according to embodiments of the inventive concept.

In one or more embodiments, the second polyimide layer 702 may comprise the same material as used to form the first polyimide layer 238 (e.g., Kapton®, or another polymer), although embodiments are not limited thereto. Alternatively, in other embodiments, the first polyimide layer 238 and the second polyimide layer 702 may comprise different materials. The second polyimide layer 702 may comprise a photosensitive polyimide material which is deposited over the upper surface of the wafer using a known deposition process (e.g., chemical vapor deposition (CVD), atomic layer deposition (ALD), etc.). The photosensitive polyimide material is then patterned using standard photolithography, followed by an etching process to define the shape and dimensions of the second polyimide layer 702. As will be described below in conjunction with FIG. 8, an etchant selective to the polyimide material (i.e., an anisotropic etching process) can be used to form trenches in the second polyimide layer 702. The trenches are not explicitly shown in FIG. 7, but can be the same as the trenches 308 shown in FIG. 3.

It is to be understood that the second polyimide layer 702 need not extend entirely over the edge termination region 14. For example, in one or more embodiments, the second polyimide layer 702 may be configured to extend horizontally across a portion of the top surface of the polyimide layer 238, with the end 706 of the second polyimide layer 702 disposed on the top surface of the first polyimide layer 238 between the inside edge 14A and the outside/peripheral edge 14B of the edge termination region 14. In some embodiments, the second polyimide layer 702 is configured to cover a majority of the edge termination region 14 (e.g., about 50 percent or more).

Assuming the top surface of the second polyimide layer 702 is shaped about the same as the top surface of the mold compound 402 shown in FIG. 6, the creepage distance will be about the same. Specifically, with the passivation structure configured in the manner shown in FIG. 7, conductor ions moving between the drain contact 218 and the source electrode 216 must travel horizontally across a bottom surface of the mold compound 402, vertically up a side surface of the mold compound 402 and a side surface of the second polyimide layer 702 (coplanar with the outer edge 704 of the semiconductor device 700), horizontally across the top surface of the second polyimide layer 702, and vertically along the end 706 of the second polyimide layer 702, eventually reaching the source electrode 216. A possible advantage of the passivation structure shown in FIG. 7 compared to the passivation structure of FIG. 6, however, may be that the material used to form the second polyimide layer 702 is less costly than the mold compound 402 for providing the same or similar creepage distance in the semiconductor device 700.

The passivation structure shown in FIG. 7 may, in some embodiments, be combined with one or more of the techniques described in conjunction with FIGS. 3-6. For example, the technique used to form corrugations in the top surface of the first polyimide layer 302 shown in FIG. 3 may also be used to provide a corrugated (or otherwise non-planar) top surface of the second polyimide layer 702, as previously stated. By way of example only and without limitation, FIG. 8 is a cross-sectional view depicting at least a portion of an exemplary semiconductor device 800 including a passivation structure comprising a second polyimide layer having a corrugated top surface, according to one or more embodiments of the present disclosure. In this illustrative embodiment, the mold compound 402 may be configured having a top surface that is coplanar with the top surface of the first polyimide layer 238.

The second polyimide layer 702, which may comprise a photo-definable material, may be formed (e.g., blanket-deposited) on the upper surface of the mold compound 402, the upper surface of the first polyimide layer 238, and a portion of the upper surface of the source electrode 216 using a deposition process (e.g., CVD, ALD, etc.). The second polyimide layer 702 is then selectively patterned, for example using a standard photolithographic process, followed by etching to form one or more trenches 802 extending vertically at least partially into the second polyimide layer 702. In one or more embodiments, an etchant is used that is selective to the second polyimide layer 702. In some embodiments, the first polyimide layer 238 and/or the mold compound 402 may be used as an etch-stop layer, particularly when the trenches are to be etched entirely through the second polyimide layer 702. Although not explicitly shown, rather than stopping at the upper surface of the first polyimide layer 238, the etching process may continue such that the trenches 802 extend at least partially into the first polyimide layer 238. In other embodiments (not shown) the etching step may not etch fully through the second polyimide layer 702 (i.e., the trenches 802 are not as deep as shown in FIG. 8). The depth and number of trenches 802 in the second polyimide layer 702 may be configured to provide a desired creepage distance in the semiconductor device 800.

In an alternative embodiment, the corrugated top surface of the second polyimide layer 702 may be provided by forming trenches (not explicitly shown) in the first polyimide layer 238 and/or mold compound 402 to thereby create a corrugated contour of the top surface of the first polyimide layer 238 and/or mold compound 402. The second polyimide layer 702 is then conformally formed (e.g., deposited) on the top surface of the first polyimide layer 238 and the mold compound 402. Assuming a substantially uniform cross-sectional thickness of the second polyimide layer 702, a contour of the top surface of the second polyimide layer 702 will closely match the corrugated contour of the top surface of the underlying first polyimide layer 238 and/or mold compound 402.

With the passivation structure configured in the manner shown in FIG. 8, conductor ions moving from the drain contact 218 to the source electrode 216 (assuming the drain contact 218 is at a higher potential relative to the source electrode 216) will travel horizontally across a bottom surface of the mold compound 402, vertically up the outer edge 704 of the mold compound 402 and second polyimide layer 702, horizontally across the corrugated top surface of the second polyimide layer 702 (which is greater than the distance across the planar top surface of the second polyimide layer 702 shown in FIG. 7), and eventually reaching the source electrode 216. Compared to the passivation structure shown in FIG. 7, the creepage distance in the semiconductor device 800 of FIG. 8 would be greater.

Embodiments of the present disclosure are directed to pre-packaged die, which may include bare die (i.e., single unpackaged die) and bare die in a housing (i.e., multiple die on a baseplate or other substrate). By way of example and without limitation, using techniques according to embodiments of the inventive concept, a 4H-SiC (a silicon carbide polytype) power device with a voltage rating of greater than 600 volts for use in a gel-filled power module with silver-sintered backside may achieve an HV-H³TRB lifetime of greater than about 2,000 hours.

It will be understood that, although ordinal terms such as “first,” “second,” etc., may be used herein to describe various elements, these elements should not be limited by such terms. These terms are only used to distinguish one element from another and should not be interpreted as conveying any particular order of the elements with respect to one another. For example, a first element could be termed a second element, and, similarly, a second element could be termed a first element, without departing from the scope of the present disclosure. As may be used herein, the term “and/or” when used in conjunction with an associated list of elements is intended to include any and all combinations of one or more of the associated listed elements. For example, the phrase “A and/or B” is intended to include element A alone, element B alone, or elements A and B.

The terminology used herein is for the purpose of describing particular embodiments of the inventive concepts only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” as used herein, are intended to specify the presence of stated features, integers, steps, operations, elements, and/or components, but do not necessarily preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

In accordance with embodiments of the present disclosure described herein, when an element such as a device or circuit, for example, is referred to as being “connected” or “coupled” to another element, it is to be understood that the element can be directly connected or coupled to the other element or intervening elements may be present. In contrast, when an element is referred to as being “directly connected” or “directly coupled” to another element, it is intended that there are no intervening elements present.

Relative terms such as, for example, “below,” “above,” “upper,” “lower,” “horizontal,” “lateral,” “vertical,” and like terms, may be used herein to describe a relationship of one element, layer or region to another element, layer or region as illustrated in the figures. It will be understood, however, that these terms are intended to encompass different orientations of a device or structure in place of or in addition to the orientation depicted in the figures.

As previously stated, like reference numbers and/or labels, as may be used herein, are intended to refer to like elements throughout the several drawings. Thus, the same numbers and/or labels may be described with reference to other drawings even if they are neither explicitly mentioned nor described in the corresponding drawing. Moreover, an element that is not denoted by a reference number or label in a given drawing may be described with reference to other drawings in which the same or similar element is designated by reference number or label.

In the drawings and specification, there have been disclosed typical embodiments of the invention and, although specific terms may be employed, they are intended to be used in a generic and descriptive sense only and not for purposes of limitation, the scope of the invention being set forth in the appended claims.

1. A semiconductor device, comprising:
a drift region comprising an active region, including at least one active element therein, and an edge termination region around at least a portion of a perimeter of the active region when viewed in plan view; and
a passivation structure on the edge termination region, the passivation structure comprising:
an insulating layer on the drift region; and
a first polymer layer on the insulating layer opposite the drift region,
wherein the first polymer layer comprises a top surface that is nonplanar.

2. The semiconductor device according to claim 1, wherein the first polymer layer is configured to extend horizontally, parallel to a top surface of the drift region, from a peripheral edge of the edge termination region toward the active region over a majority of the edge termination region.

3. The semiconductor device according to claim 1, wherein the first polymer layer is configured to extend horizontally, parallel to a top surface of the drift region, from a peripheral edge of the edge termination, across the top surface of the insulating layer, and partially into the active region.

4. The semiconductor device according to claim 1, wherein the first polymer layer comprises a polyimide.

5. The semiconductor device according to claim 1, wherein the insulating layer comprises an oxide.

6. The semiconductor device according to claim 1, wherein the top surface of the first polymer layer comprises one or more openings extending vertically, perpendicular to the top surface of the drift region, at least partially into the first polymer layer.

7. The semiconductor device according to claim 1, wherein the first polymer layer comprises a first end and a second end opposite the first end, the first end of the first polymer layer is vertically coplanar with a peripheral edge of the edge termination region, and the second end of the first polymer layer is over a top surface of a source electrode of a metal-oxide-semiconductor field-effect transistor in the active region.

8. The semiconductor device according to claim 1, further comprising a second polymer layer between the insulating layer and the first polymer layer.

9. The semiconductor device according to claim 8, wherein the second polymer layer comprises a planar top surface.

10. The semiconductor device according to claim 8, wherein the second polymer layer comprises one or more trenches extending vertically from a top surface of the second polymer layer at least partially into the second polymer layer, and wherein the first polymer layer conformally covers at least a portion of the top surface of the second polymer layer.

11. The semiconductor device according to claim 1, further comprising a mold compound on a peripheral edge of the edge termination region, the mold compound extending around the semiconductor device when viewed in plan view.

12. The semiconductor device according to claim 11, wherein a top surface of the mold compound is coplanar with the top surface of the first polymer layer.

13. The semiconductor device according to claim 11, wherein at least one of a top surface, a side surface and a bottom surface of the mold compound comprises at least one trench therein extending at least partially into the mold compound.

14. (canceled)

15. A semiconductor device, comprising:
a drift region;
an active region comprising a portion of the drift region;
an edge termination region in the drift region and around at least a portion of a perimeter of the active region when viewed in plan view; and
a passivation structure on the edge termination region, the passivation structure comprising:
an insulating layer on the drift region;
a first polymer layer on the insulating layer opposite the drift region; and
a mold compound on a peripheral edge of the edge termination region, wherein the mold compound does not extend over a top surface of the active region.

16. The semiconductor device according to claim 15, wherein the top surface of the first polymer is substantially planar.

17. The semiconductor device according to claim 15, wherein at least one of the top surface, a side surface and a bottom surface of the mold compound comprises at least one trench therein.

18. The semiconductor device according to claim 15, wherein the mold compound extends around the peripheral edge of the edge termination region when viewed in plan view.

19. The semiconductor device according to claim 15, wherein the top surface of the first polymer layer has a nonplanar cross-sectional profile.

20. The semiconductor device according to claim 15, wherein the active region includes at least one metal oxide semiconductor field effect transistor (MOSFET), the semiconductor device further comprising a second polymer layer on the first polymer layer and the mold compound, the second polymer layer extending horizontally from an outer edge of the mold compound, opposite the peripheral edge of the edge termination region, to a top surface of a source electrode of the MOSFET in the active region.

21.-28. (canceled)

29. A method of forming a semiconductor device, the method comprising:
providing a drift region comprising an active region, including at least one active element therein, and an edge termination region around at least a portion of a perimeter of the active region when viewed in plan view; and
providing a passivation structure on the edge termination region, the passivation structure comprising:
an insulating layer on the drift region; and
a first polymer layer on the insulating layer opposite the drift region, and then forming at least one notch in the first polymer layer.

30.-71. (canceled)
